(19) United States
(12) Patent Application Publication
(10) Pub. No.: US 2026/0271668 A1
(43) Pub. Date: Sep. 10, 2026

(54) METHODS AND ASSEMBLIES FOR REMOVING A DIE FROM A FOIL

(71) Applicant: Ismeca Semiconductor Holding SA, La Chaux-de-Fonds (CH)

(72) Inventors: Fabio Depetris, Renan (CH); Adrien Bardoux, Maîche (FR); Giovanni Palmisano, La Chaux-de-Fonds (CH)

(21) Appl. No.: 19/163,748

(22) PCT Filed: Mar. 10, 2023
(86) PCT No.: PCT/IB2023/052325

§ 371 Date: Sep. 9, 2025

(51) Int. Cl. H10P 72/70; H10P 56/00

(52) U.S. Cl. CPC H10P 72/744; H10P 56/00

(57) ABSTRACT

According to the present invention there is provided a method of removing a die (2) from a foil (3), comprising the steps of, (a) providing a foil (3) which has a first surface (3a) and a second, opposite surface (3b) wherein the foil (3) has one or more die (2) attached to the first surface (3a); (b) aligning a vibration member (6) with a die (2) which is to be removed from the foil; (c) while maintaining said alignment moving the vibration member (6) to bring it into contact with the second surface (3b) of the foil (3); (d) continuing to move the vibration member (6) from a start position, a predefined distance in a direction towards the foil (3); (e) vibrating the vibration member (6), to generate vibrations in the foil (3) which loosen the die (2) from the first surface (3a) of the foil (3); (f) picking the loosened die (2) from the first surface (3a) of the foil (3). There is further provided a corresponding assembly (1) which can be used to perform the method.

### FIELD OF THE INVENTION

The present invention concerns methods for removing a die from a first surface of foil, which involves moving a vibration member in a direction towards; and vibrating the vibration member, to generate vibrations in the foil which loosen the die from the first surface of the foil; and then picking the loosened die from the first surface of the foil. There is further provided assemblies which can be used to remove a die from a foil.

### BACKGROUND

FIGS. 1a and 1b illustrates the steps involved in existing methods which are used to remove a die 101 which attached to a first surface 103a of a foil 103. These existing methods involve aligning a tip 105a of a needle 105 beneath the die 101 which is to be removed; and pressing a tip 105a of a needle 105 against a second, opposite, surface 103b of the foil 103, to create a curvature 106 in the foil 103 which results in a reduction contact area between the die 101 and the foil 103. Reducing the contact area reduces the adhesion force holding the die 101 on the first surface 103a of the foil 103, thereby allowing a pickup head 107 to pick the die 101 by vacuum from the foil 103. Disadvantageously dies often become damaged when they are removed from the foil in this way; not only the die which is being removed but also neighbouring dies often become damaged.

The size of the space 108 between adjacent dies 101 on a foil 103 is dictated by the wafer dicing operation which involves cutting the wafer to produce the dies 101; in order to reduce the amount of waste material it is desirable to minimize the width of the cutting line. Usually, the width of the cutting line is less than 15 μm. The width of the cutting line is expected to reduce even further in the future as technology and techniques advance. After the dicing operation the diced wafer is positioned on the first surface 103a of the foil 103; the first surface 103a of the foil 103 has adhesive so that each die 101 become attached to the first surface 103a of the foil 103. The size of the space 108 between adjacent dies 101 on a foil 103 corresponds to the width of the cutting line. The narrow width of the cutting line means that when the diced wafer is positioned on the first surface 103a of the foil 103 there is only a very small gap between adjacent dies on the foil. For example, the width of the cutting line is usually less than 15 μm, so usually the width of the space 108 between adjacent dies 101 on a foil 103 is less than 15 μm. Disadvantageously, in existing methods, if the gap between adjacent dies is small, then when the tip 105a of the needle 105 is moved against the second, opposite, surface 103b of the foil 103 to create a curvature 106 in the foil 103, adjacent dies 101 will contact one another and become damaged (e.g. dies may become chipped). So, the existing methods used to remove a die from a foil is a bottleneck to reducing the width of the cutting lines and thus is a bottleneck to achieving further reduction in waste material.

It is an aim of the present invention to obviate or mitigate at least some of the disadvantages associated with the existing methods for removing a die from a foil.

### SUMMARY OF THE INVENTION

According to the present invention, this aim is achieved by, any of the methods for removing a die from a foil, comprising either the steps recited in independent claim 1 or the steps recited in independent claim 28; and/or by any of the assemblies having the features recited in, either independent claim 14 or independent claim 37. The dependent claims recite favourable, optional, features/steps of various embodiments of the inventions.

### SHORT DESCRIPTION OF THE DRAWINGS

Exemplary embodiments of the invention are disclosed in the detailed description and illustrated by the drawings in which:

FIGS. 1a and 1b illustrate a prior art method used to remove a die from a foil;

FIG. 2 provides a front view of an assembly according to an embodiment of the present invention, which can be used to remove a die from a foil;

FIG. 3 provides a front view of an assembly according to another embodiment of the present invention, which can be used to remove a die from a foil;

FIG. 4 provides a front view of an assembly according to another embodiment of the present invention, which can be used to remove a die from a foil;

FIG. 5 provides a front view of an assembly according to another embodiment of the present invention, which can be used to remove a die from a foil;

FIGS. 6a and 6b provides a front view illustrating adjacent dies on the foil coming into contact when the foil is too slack;

FIGS. 7a-7d illustrate the steps taken in exemplary calibration step.

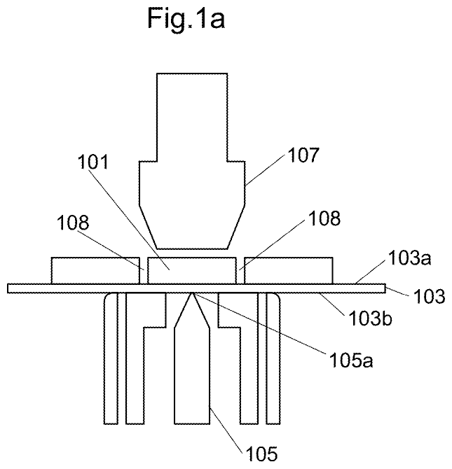

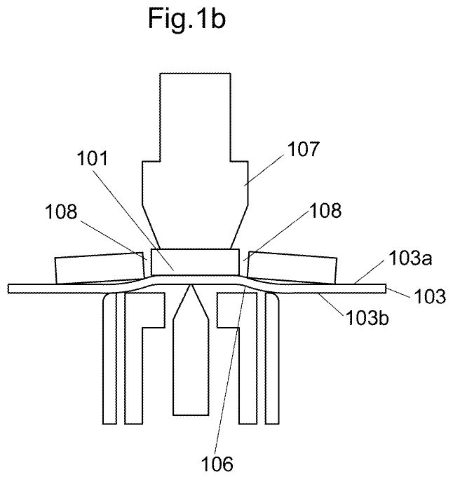

### DETAILED DESCRIPTION OF THE DRAWINGS

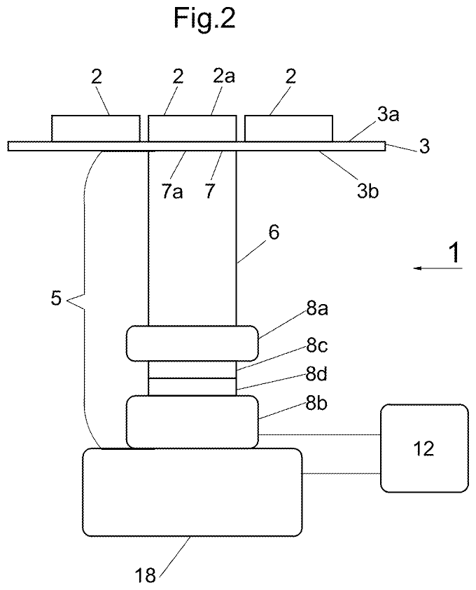

FIG. 2 provides a front view of an assembly 1 according to an embodiment of the present invention, which can be used to remove a die 2a from a foil 3. The foil 3 has a first surface 3a and a second, opposite, surface 3b; a plurality of dies 2 are attached to the first surface 3a. In this exemplary embodiment each of the plurality of dies 2 are attached by adhesive to the second surface 3b of the foil 3.

The assembly 1 comprises a vibration unit 5 which comprises a vibration member 6 which is attached to the vibration unit 5. The vibration member 6 has a free end 7a; the vibration member 6 can be moved so that a surface 7 of the free end 7a contacts the foil 3 to which the die 2 is attached.

In this embodiment the surface 7 of the free end 7a of the has a flat profile. Most preferably the flat surface 7 of the free end 7a has the same shape as the surface of the die 2 which is attached to the foil 3. In this embodiment the flat surface 7 of the free end 7a has a square-shaped perimeter; the flat surface 7 of the free end 7a preferably has an area between 0.2 mm*0.2 mm to 1 mm*1 mm. In should be understood that the surface 7 of the free end 7a of the vibration member 6 may have any suitable profile; for example, in another embodiment the surface 7 of the free end 7a of the vibration member 6 comprises a plurality of ridges. In should also be understood that the surface 7 of the free end 7a of the vibration member 6 may have any suitable size; for example, in another embodiment the surface 7 of the free end 7a has an area between 2 mm*2 mm to 12 mm*12 mm. Most preferably the surface of the free end 7a has an area between 0.2 mm*0.2 mm to 1 mm*1 mm when the die 2 which is to be removed from the foil 3 has a size 0.2 mm*0.2 mm to 1 mm*1 mm; and surface of the free end 7a has an area between 2 mm*2 mm to 12 mm*12 mm when the die 2a which is to be removed from the foil 3 has a size between 2 mm*2 mm to 12 mm*12 mm. Most preferably the surface 7 of the free end 7a has an area between which is in the range of 80%-120% the area of the surface of the die 2 which is attached to the foil 3. Most preferably the shape of the surface 7 of the free end 7a has the same shape as the surface of the die 2 which is attached to the foil 3. It should also be understood that the surface 7 of the free end 7a is not limited to having a square-shaped perimeter, for example, in another embodiment the surface of the free end 7a has a circular perimeter.

In this embodiment the vibration member 6 is removably attached to the vibration unit 5. In a preferred embodiment the assembly 1 comprises a plurality of different vibration members 6, having different sized surfaces 7 at their respective free ends 7a and/or having different surface profiles at their respective free ends 7a and/or having different shaped of surfaces 7 at their respective free ends 7a; each of the different vibration members 6 can be selectively removably attached to the vibration unit 5. A user can select to attach any of different vibration members to the vibration unit 5 depending on characteristics (e.g. size) of the die 2a which is to be removed from the foil. For example, if dies having a size between 0.2 mm*0.2 mm to 1 mm*1mmare to be removed from the foil 3 then the user may select to attach a vibration member 6 that has a free end 7a with a square surface having an area between 0.2 mm*0.2 mm to 1 mm*1 mm; if dies having a size between 2 mm*2 mm to 12 mm*12 mm are to be removed from the foil 3 then the user may select to attach a vibration member 6 that has a free end 7a with a square surface having an area between 2 mm*2 mm to 12 mm*12 mm.

In the embodiment shown in FIG. 2 the vibration unit 5 comprises an ultrasonic transducer 5 and the vibration member 6 comprises a sonotrode 6. However, it should be understood that the present invention is not limited to requiring an ultrasonic transducer 5 and sonotrode 6; for example in another embodiment the vibration unit 5 comprises a high speed motor, and/or a high speed voice coil actuator and/or a pneumatic turbine, which is operable to move the vibration member 6 at high speeds so as to achieve the effect of vibration of the vibration members 6.

The vibration unit 5 is operable to vibrate the vibration member 6 at a predefined frequency. In the embodiment shown in FIG. 2, the vibration unit 5 is configured to vibrate the vibration member 6 at a frequency between 80 kHz-110 KHz.

In the assembly 1 it is the design of the vibration member 6 which enables a vibration in the frequency between 80 kHz-110 kHz to be achieved. Specifically, the vibration member 6 comprises a first block section 8a, and a second block section 8b, and a first piezoelectric section 8c and a second piezoelectric section 8d. Preferably, the vibration unit comprise ultrasonic transducer 5 which is configured to resonate on it first mode of vibration at 80 KHz.

The vibration unit 5 is configured to vibrate the vibration member 6 with a constant amplitude of vibration between 2 μm-10 μm. Most preferably the vibration unit 5 is configured to vibrate the vibration member 6 with a constant amplitude of vibration up to 10 μm; the level of voltage applied to the vibration unit 5 is then adjusted to achieve a predefined constant amplitude of vibration of the vibration member 6. For example, in order to increase the amplitude of vibration of the vibration member the level of voltage which is supplied to the vibration unit 5 is increased; in order to decrease the amplitude of vibration of the vibration member the level of voltage which is supplied to the vibration unit 5 is decreased.

The assembly 1 further comprises a positioning unit 18, which can selectively move the vibration unit 5. The positioning unit 18 is operable to move the vibration unit 5 in 3-dimensions (in other words the positioning unit 18 is operable to move the vibration unit 5 in the x-y axis and z-axis directions). For example, the positioning unit 18 can move the vibration unit 5 so that the vibration member 6 is aligned beneath the die 2a which is to be removed from the foil 3 (i.e. along the x & y axes); and the positioning unit 18 can selectively move the vibration unit 5 towards the foil 3 or away from the foil 3 (i.e. along the z axis). It should be understood that because the vibration member 6 is attached to the vibration unit 5, moving the vibration unit 5 will move the vibration member 6; for example if the vibration unit 5 is moved in an direction away from the foil 3 the vibration member 6 will be moved in a direction away from the foil; likewise if the vibration unit 5 is moved in an direction towards the foil 3 the vibration member 6 will be moved in a direction towards the foil 3.

The assembly 1 further comprises a controller 12 which is operably connected to the positioning unit 18; the controller 12 is configured to operate the positioning unit 18 to move the vibration unit 5 relative to the foil 3.

Specifically, the controller 12 is configured to operate the positioning unit 18 to move the vibration unit 5 in a direction which is towards the foil 3 or in a direction which is away from the foil 3. In this embodiment the controller 12 is also configured to operate the positioning unit 18 to move the vibration unit 5 so that the vibration member 6 is aligned below the die 2a to be removed. In other words the controller 12 is configured to operate the positioning unit 18 to move the vibration unit 5 along the x-y axes and also along the z-axis.

The controller 12 is configured to operate the positioning unit 18 to move the vibration unit 5 so that the vibration member 6 is aligned with the die 2a which is to be removed from the foil. The die 2a which is to be removed is attached to the first surface 3a of the foil 3 while the vibration member 6 will be opposite the second surface 3b of the foil; so the vibration member 6 will be aligned beneath the die 2a, but the foil 3 will be interposed between the foil and die 2a which is to be removed from the foil 3.

While maintaining said alignment of the vibration member 6 with the die 2a to be removed, the controller 12 is configured to operate the positioning unit 18 to move the vibration unit 5 so that the vibration member 6 is brought into contact with the second surface 3b of the foil 3. At this point the vibration member 6 will simply touch the second surface 3b of the foil 3, and will not apply any substantial force to the foil 3. In this embodiment the vibration member 6 is considered to be an a start position when the vibration member 6 simply touches the second surface 3b of the foil 3.

The controller 12 is configured to operate the positioning unit 18 to move the vibration unit 5 so that the vibration member 6 moves from the start position, a predefined distance in a direction towards the foil 3.

The controller 12 is further operably connected to the vibration unit 5. the controller 12 is configured to initiate the vibration unit 5 to vibrate the vibration member 6, to generate vibrations in the foil 3 which loosen the die 2a from the first surface 3a of the foil 3, once the vibration member 6 has been move from the start position, a predefined distance in a direction towards the foil. However, it is not essential that the controller 12 be configured to initiate the vibration unit 5 to vibrate the vibration member 6.

Once the die 2a has been loosened the die 2a is picked from the first surface 3a of the foil 3. Preferably the assembly 1 further comprises a pickup head which is operable to pick the loosened die from the foil 3; the pickup head preferably holds the loosened die by means of a vacuum. The pickup head may be provided on a rotatable turret; the rotatable turret preferably comprises a plurality of pickup heads; preferably when a pickup head on the turret has picked a loosened die from the foil, that pickup head will hold said die by means of a vacuum; the turret will then rotate to move the next pickup head on the turret into a position where it can pick the next die loosened from the foil 3.

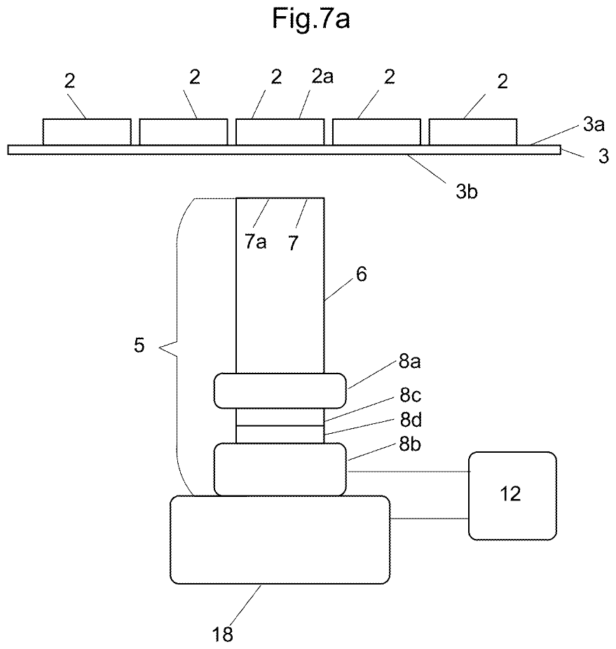

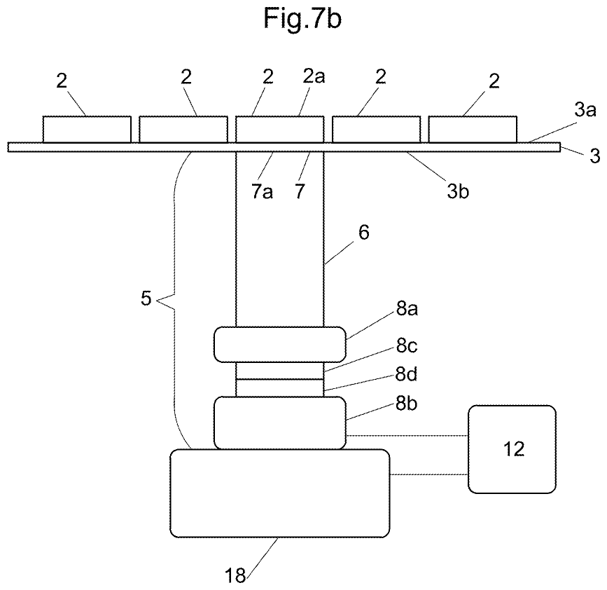

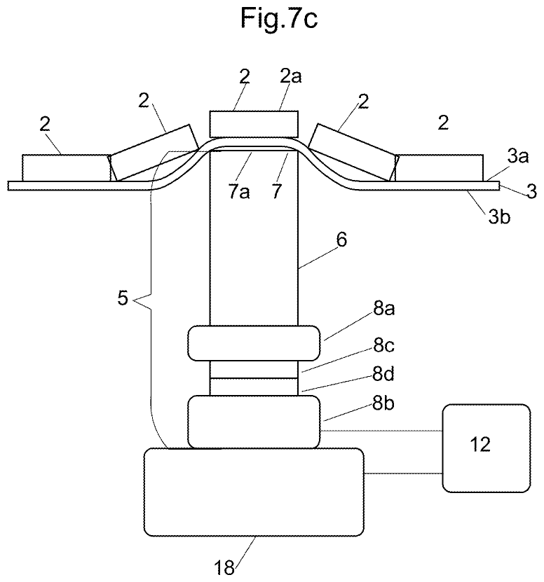

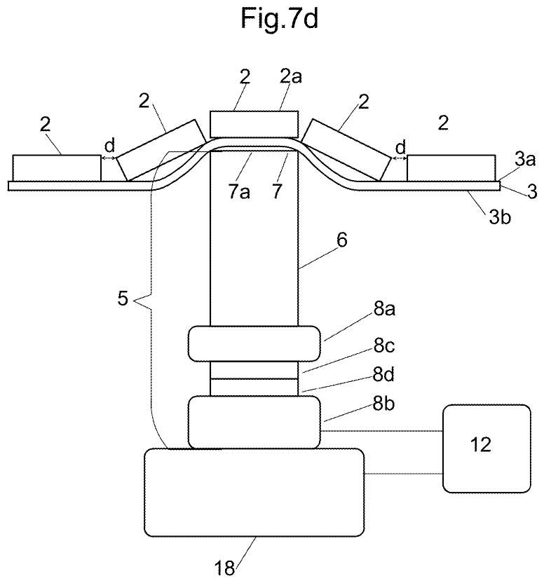

A calibration step may be carried out to determine said predefined distance. FIGS. 7a-7d illustrates steps taken in an exemplary calibration step carried out when using the assembly 1; however it should be understood that the calibration step is the same when using the assembly 20.

The calibration step comprises: providing the foil 3 from which the die 2a is to be removed. The controller then operates the positioning unit 18 to move the vibration unit 5 so that the vibration member 6 is aligned with the die 2a which is to be removed from the foil (as shown in FIG. 7a). While maintaining said alignment of the vibration member 6 with the die 2a to be removed, the controller 12 operates the positioning unit 18 to move the vibration unit 5 so that the vibration member 6 is brought into contact with the second surface 3b of the foil 3 (as shown in FIG. 7b). The controller 12 operates the positioning unit 18 to continue to move the vibration unit 5 and thus the vibration member 6 in the direction of the foil 3 until a least two die 2 on the first surface 3a of the foil 3 come into contact one another (as shown in FIG. 7c)—when the vibration unit 5 and thus the vibration member 6 continue to be moved in the direction of the foil 3, foil will be elastically deformed by the vibration member 6 thereby creating a curvature in the foil which results in some adjacent dies being moved closer to one another; the vibration member 6 is moved far enough in the direction of the foil the curvature will increase so that some adjacent dies 2 on the foil 3 will contact one another (i.e. the distance between a least two adjacent die on the foil is zero). In a preferred embodiment the assembly 1 further comprises a camera which is configured to capture images which show all of the die 2 on the foil 3; the controller 12 is further operably connected to the camera so that the controller 12 receives said images; the controller 12 is further configured to carry out processing of said images to determine the distance between adjacent dies on the foil. Alternatively, the foil can be manually inspected for contact between adjacent die 2.

Once the controller 12 has determined from said images captured by the camera that the distance between a least two adjacent die on the foil is zero (i.e. at least two adjacent die contact one another), the controller 12 then operates the positioning unit 18 to move the vibration unit 5 in a direction away from the foil until there is a at least a distance ‘d’ in the range 2 μm-5 μm between the die 2 that were previously in contact with one another (as shown in FIG. 7d). Preferably the controller 12 then operates the positioning unit 18 to move the vibration unit 5 in a direction away from the foil until there is at least a distance in the range 2 μm-5 μm between all adjacent dies on the foil. Most preferably the force which the vibration member 6 applies to the foil should be maximized, hence the controller 12 operates the positioning unit 18 to move the vibration unit 5 a minimum amount in the direction away from the foil to achieve a distance in the range 2 μm-5 μm between all adjacent dies on the foil (or, at least a minimum amount in the direction away from the foil to achieve a distance in the range 2 μm-5 μm between the die 2 that were previously in contact with one another).

When there is a distance in the range 2 μm-5 μm between the die 2 that were previously in contact with one another vibration member is then at an end position. Or, when there is a distance in the range 2 μm-5 μm between all adjacent dies on the foil then the vibration member is then at an end position. The controller 12 further comprises a processor which is configured to determine said predefined distance as being the difference between said start position and the end position. Typically, the predefined distance is in the range 0.1 mm-0.5 mm.

In an embodiment the assembly may further comprise a force sensor 11 which is operably connected to the vibration unit 5 so that the force sensor 11 can sense the force which the vibration member 6 applies to the foil 3. The controller is further operably connected to the force sensor and is configured to operate the positioning unit to move the vibration unit in a direction which is towards the foil if the measurement of the force sensor falls below a threshold minimum force, until the vibration member applies a force to the foil which is above said threshold minimum force; and to operate the positioning unit to move the vibration unit in a direction which is away from the foil if the measurement of the force sensor exceeds a threshold maximum force, until the vibration member applies a force to the foil which is below said threshold maximum force. This ensures that the force which the vibration member 6 applies to the foil 3, during vibration, can be maintained within a predefined range which is between the threshold minimum force and threshold maximum force. The threshold minimum force may be 0.1N; the threshold maximum force maybe 0.3N. The controller 12 can operate the positioning unit 18 to move the vibration unit 5 in a direction which is towards the foil 3 or in a direction which is away from the foil 3, when the vibration member 6 is vibrating and/or when the vibration member 6 is not vibrating.

The vibration member 6 generates vibrations in the foil 3 which loosen the die 2 from the first surface 3a of the foil 3. Preferably the assembly 1 further comprises a pickup head which is operable to pick the loosened die from the foil 3; the pickup head preferably holds the loosened die by means of a vacuum. The pickup head may be provided on a rotatable turret; the rotatable turret preferably comprises a plurality of pickup heads; preferably when a pickup head on the turret has picked a loosened die from the foil, that pickup head will hold said die by means of a vacuum; the turret will then rotate to move the next pickup head on the turret into a position where it can pick the next die loosened from the foil 3.

According to a further aspect of the present invention there is provided a method of removing a die from a foil. The assembly 1 can be used to perform an embodiment of said method.

The method may comprise the steps of,
(a) providing a foil 3 which has a first surface 3a and a second, opposite surface 3b wherein the foil 3 has one or more die 2a attached to the first surface (3a);
(b) aligning a vibration member 6 with a die 2a which is to be removed from the foil;
(c) while maintaining said alignment moving the vibration member 6 to bring it into contact with the second surface 3b of the foil 3;
(d) continuing to move the vibration member 6 from a start position, a predefined distance in a direction towards the foil 3;
(e) vibrating the vibration member 6, to generate vibrations in the foil (3) which loosen the die 2a from the first surface 3a of the foil 3;
(f) picking the loosened die 2a from the first surface 3a of the foil 3.

In a preferred embodiment the method further comprise a calibration step which comprises the steps of: providing the foil to be used in step (a), which has a first surface and a second, opposite surface wherein the foil has one or more die attached to the first surface; aligning the vibration member with a die 2a which is to be removed from the foil; while maintaining said alignment moving the vibration member from the start position to bring the vibration member into contact with the second surface of the foil; continuing to move the vibration member until a least two die contact one another; moving the vibration member in a direction away from the foil until there is a distance in the range 2 μm-5 μm between said two die, wherein when there is a distance in the range 2 μm-5 μm between said two die the vibration member is at an end position; determining said predefined distance as being the difference between said start position and the end position.

In one embodiment said calibration steps is carried out before performing steps (a)-(f). In another embodiment the calibration step may be carried out after step (c), in which case the step (d) is replaced by the calibration step. For example the calibration step may be carried out when removing the first die from the foil; so, in an embodiment, after the steps (a)-(c) have been carried out for the first die to be removed from the foil, the calibration step may then be carried out, and then steps (e) and (f) are carried out after the calibration step to remove the first die 2a from the foil 3. Since the predefined distance will then be known, for removal of each of the subsequent die 2 from the foil 3 the steps (a)-(f) are carried out without the need to carry out the calibration step again.

In an embodiment the further comprises measuring the force that the vibration member is applying to the foil after the vibration member is moved from the start position, the predefined distance in a direction towards the foil; and moving the vibration member in a direction towards the foil or in a direction away from the foil, until the vibration member applies a force to the foil which is within a predefined initial force range, before performing steps (e) and (f). The predefined initial force range in the range 0.1N-0.3N; most preferably the predefined initial force range is 0.15N.

In an embodiment the method further comprises measuring the force that the vibration member is applying to the foil when the vibration member is vibrating in step (e) and/or measuring the force that the vibration member is applying to the foil when the vibration member is moved from the start position, the predefined distance in a direction towards the foil; and moving the vibration member in a direction which is towards the foil if the measurement of the force sensor falls below a threshold minimum force, until the vibration member applies a force to the foil which is above said minimum threshold. In an embodiment the further comprises measuring the force that the vibration member is applying to the foil when the vibration member is vibrating in step (e) and/or measuring the force that the vibration member is applying to the foil when the vibration member is moved from the start position, the predefined distance in a direction towards the foil; and moving the vibration member in a direction which is away from the foil if the measurement of the force sensor exceeds a threshold maximum force, until the vibration member applies a force to the foil which is below said threshold maximum force. The threshold minimum force may be 0.1N; the threshold maximum force may be 0.3N. It should be understood that in the assembly 1, because the vibration member 6 is attached to the vibration unit 5, moving the vibration member 6 away from the foil 3 can be achieved by moving the vibration unit 5 away from the foil 3; likewise, moving the vibration member 6 towards the foil 3 can be achieved by moving the vibration unit 5 towards the foil 3. The movement of the vibration unit 5 may be done by the positioning unit 18 which is operated by the controller 12.

In a preferred embodiment the step (e) of vibrating the vibration member 6 comprises vibrating the vibration member 6 at a frequency between 80 kHz-110 kHz. Preferably the vibration member 6 vibrates with a constant amplitude of vibration between 2 μm-10 μm. The method may comprise the step of adjusting the level of voltage applied to the vibration unit 5 to achieve a predefined constant amplitude of vibration of the vibration member 6. For example, in order to increase the amplitude of vibration of the vibration member the level of voltage which is supplied to the vibration unit 5 is increased; in order to decrease the amplitude of vibration of the vibration member the level of voltage which is supplied to the vibration unit 5 is decreased.

In an embodiment the method further comprises the step of, identifying if two or more die 2 on the foil 3 come into contact during step (e). Identifying, if two or more die 2 on the foil 3 come into contact can be done using any suitable means, such as using a camera which captures images/video of the die on the foil. In an embodiment, if it is identified that two or more die 2 on the foil 3 come into contact during step (e), a step of moving the vibration member 6 away from the foil 3 (preferably moving the vibration member 6 away from the foil 3 so that the vibration member 6 no longer contacts the foil 3); and then transferring all of (or at least some of) die 2 that are on the foil 3 to another, stiffer, foil. After the die have been transferred to the stiffer foil, the method steps (a)-(f) are then carried out to remove the die from the surface of the stiffer foil.

In an embodiment of the method a step of applying a vacuum to the second surface 3b of the foil 3 to maintain the parts of the foil 3, flat, at least when steps (d) and/or (e) and/or (f) are being carried out. Most preferably a vacuum is applied parts of the foil 3 which are adjacent to the part of the foil 3 on which the die 2a to be removed is attached, so as to prevent the adjacent dies 2 which are mounted on the foil from becoming displaced from the foil 3 when steps (d) and/or (e) and/or (f) are being carried out to remove the die 2a from the foil 3. Specifically by applying a vacuum to the second surface of the foil when steps (d) and/or (e) and/or (f) are being performed, the vacuum will reduce the amount of curvature in the parts of the foil 3 on which the adjacent dies 2 are mounted-curvature in the foil 3 will thus be localized to the part of the foil 3 on which the die 2a which is to be removed is located—as a result the adjacent dies 2 can maintain the majority of their respective surfaces in contact with the first surface 3a of the foil, and thereby maintain a stable adhesion to the first surface 3a of the foil, which in turn reduces the risk that these adjacent dies 2 become displaced when steps (d) and/or (e) and/or (f) are performed. In an embodiment vacuum may be applied to the second surface 3b of the foil 3, during when steps (b)-(f) are being carried out.

In an embodiment of the method the vibration member 6 is used to generate vibrations in the foil 3 which loosen the die 2 from the first surface 3a of the foil 3. Preferably the loosened die is picked from the foil by a pickup head; the pickup head holds the loosened die by means of a vacuum. The pickup head may be provided on a rotatable turret; the rotatable turret preferably comprises a plurality of pickup head; preferably when a pickup head on the turret has picked a loosened die from the foil, that pickup head will hold said die by means of a vacuum; the turret will then rotate to move the next pickup head on the turret into a position where it can pick the next die loosened from the foil.

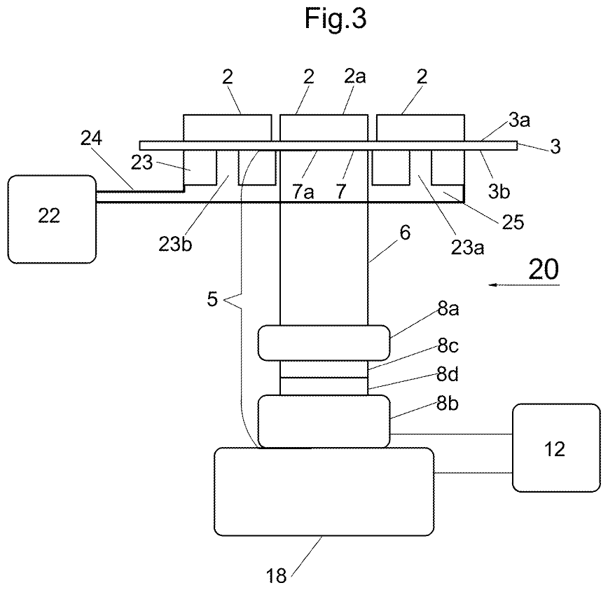

FIG. 3 provides a front view of an assembly 20 according to an embodiment of the present invention, which can be used to remove a die 2a from a foil 3. The assembly 20 has all the features of the assembly in FIG. 2, and like features are awarded the same reference numbers.

The assembly 20 further comprises a vacuum generator unit 21. The vacuum generator unit 21 comprises a vacuum generating means 22 and a plate member 23 having a plurality of through-holes 23a defined therein; each of said through-holes 23a,23b being fluidly connected to the vacuum generating means 22 via a conduit 24 and vacuum chamber 25.

Importantly in the assembly 20, the plate member 23 has at least a first through-hole 23a and a second through-hole 23b; and the plate member 23 is moved into contact with the second surface 3b of the foil 3 and arranged so that when the vibration member 6 is aligned beneath a die 2a which is to be removed from the foil 3, the first and second through-holes 23a,23b are located on opposite sides of the vibration member 6. The position of the first and second through-holes 23a,23b is such that when the vibration member 6 is aligned beneath a die 2a which is to be removed from the foil 3, the first through-hole 23a will be aligned beneath an adjacent die 2 which is on side of the die 2a which is to be removed, and the second through-hole 23b will be aligned beneath an adjacent die 2 which is on the other side of the die 2a which is to be removed. In other words position of the first and second through-holes 23a,23b is such that when the vibration member 6 is aligned beneath a die 2a which is to be removed from the foil 3, the first and second through-holes 23a,23b will be aligned beneath respective dies 2 which are adjacent to said die 2a which is to be removed.

The assembly 20 can be used to perform a method which has all of the steps of the above-mentioned method which can be performed using the assembly 1 of FIG. 2. However, this embodiment of the method further comprises the step using the vacuum generator unit 21 to apply a vacuum to the second surface 3b of the foil 3, at least during when steps (d) and/or (e) and/or (f) are being carried out. In the most preferred embodiment the vacuum is applied to the second surface 3b of the foil 3, at the parts of the second surface 3b which are aligned with the die 2 which are adjacent to the die 2a which is to be removed. It should be understood that in some cases there will be only one single die adjacent to the die 2a which is to be removed; for example if the die 2a which is to be removed in at an edge of the wafer it can be that there is only one single die adjacent to it; accordingly it should be understood that in this embodiment a vacuum may only need to be applied to one single adject die. In an embodiment the method comprises using the vacuum generator unit 21 to apply a vacuum to the second surface 3b of the foil 3, during when steps (b)-(f) are being carried out.

The vacuum will serve to maintain the parts of the foil 3 on which the adjacent dies 2 are mounted, flat, when steps (d) and/or (e) and/or (f) are being carried out, so as to prevent the adjacent dies 2 which are mounted on the foil from becoming displaced from the foil 3 when steps (d) and/or (e) and/or (f) are being carried out to remove the die 2a from the foil 3. Specifically by applying a vacuum to the second surface of the foil when steps (d) and/or (e) and/or (f) are being performed, the vacuum will the amount of curvature in the parts of the foil 3 on which the adjacent dies 2 are mounted-curvature in the foil 3 will thus be localized to the part of the foil 3 on which the die 2a which is to be removed is located—as a result the adjacent dies 2 can maintain the majority of their respective surfaces in contact with the first surface 3a of the foil, and thereby maintain a stable adhesion to the first surface 3a of the foil, which in turn reduces the risk that these adjacent dies 2 become displaced when steps (d) and/or (e) and/or (f) are performed to remove the die 2a.

In a further variation the plate member 23 may have a plurality of through-holes e.g. four through holes, allowing a vacuum to be applied to a plurality of dies which are surrounding or near to the die 2a which is to be picked. For example, if the die to be picked has four adjacent dies then a vacuum may be applied to the second surface 3b of the foil 3 so that the parts of the foil 3 on which these four adjacent dies 2 are mounted, are maintained flat (or substantially flat), when steps (d) and/or (e) and/or (f) are being carried out. In another example a vacuum may be applied to the second surface 3b of the foil 3 so that so that parts of the foil on which these dies are mounted, are maintained flat (or substantially flat), when steps (d) and/or (e) and/or (f) are being carried out (more generally a vacuum may be applied to the second surface 3b of the foil 3 so that parts of the foil on which any number of dies are mounted, are maintained flat (or substantially flat), when steps (d) and/or (e) and/or (f) are performed.

Preferably the number of through-holes in the plate member 23 will correspond to the number of parts of the foil which are to be maintained flat (or substantially flat) when steps (d) and/or (e) and/or (f) are being performed, which is equal to the number of dies on the foil that are to be protected from becoming displaced when steps (d) and/or (e) and/or (f) are being performed. In a further embodiment the plate member 23 may have one or more shutters which can selectively be moved to close a through-hole so that no vacuum can pass through the through hole.

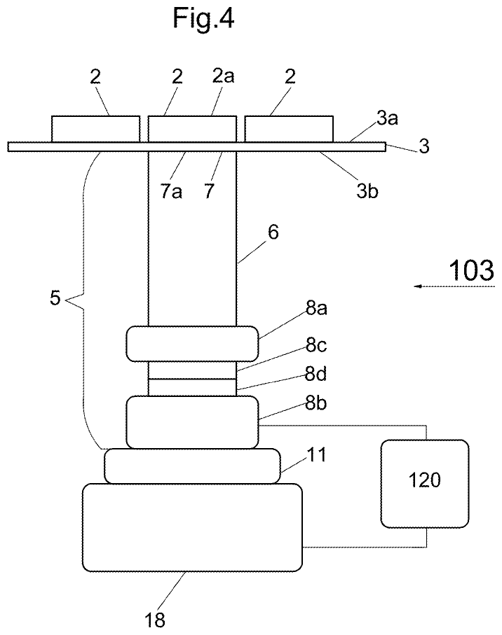

FIG. 4 provides a front view of an assembly 103 according to a further embodiment of the present invention. The assembly 103 has many of the same features as the assembly 1 in FIG. 2 and like features are awarded the same reference numbers.

The assembly 103 further comprises a force sensor 11 which is operably connected to the vibration unit 5 so that the force sensor 11 can sense the force which the vibration member 6 applies to the foil 3; the force sensor 11 can sense the force which the vibration member 6 applies to the foil 3 when vibrating, over the full amplitude of the vibrations.

The assembly 103 further comprises a controller 120 which is operably connected to the force sensor 11 so that the controller 120 can receive a measurement of the force which the vibration member 6 applies to the foil 3; the controller 120 can receive a measurement of the force which the vibration member 6 applies to the foil 3 when the vibration member 6 is vibrating, and also the controller 120 can receive a measurement of the force which the vibration member 6 applies to the foil 3 when the vibration member 6 it is not is vibrating (e.g. before the vibration member 6 is vibrated); the force which the vibration member 6 applies to the foil 3 before the vibration member 6 begins to vibrate can be considered as being an initial force which the vibration member 6 applies to the foil 3.

The controller 120 is further connected to a positioning unit 18; the controller 120 operates the positioning unit 18 depending on the force measurement the controller 120 receives from the force sensor 11. Specifically, the controller 120 operates the positioning unit 18 to move the vibration unit 5 in a direction which is towards the foil 3 or in a direction which is away from the foil 3, depending on the force measurement the controller 120 receives from the force sensor 11. It should be understood that the controller 120 can operate the positioning unit 18 to move the vibration unit 5 in a direction which is towards the foil 3 or in a direction which is away from the foil 3, when the vibration member 6 is vibrating and when the vibration member 6 is not vibrating.

In this embodiment the controller 120 is configured to operate positioning unit 18 to move the vibration unit 5 in a direction which is towards the foil 3 if the measurement of the force sensor 11 falls below a threshold minimum force. The controller 120 is further configured to operate the positioning unit 18 to move the vibration unit 5 in a direction which is away from the foil 3 if the measurement of the force sensor 11 exceeds a threshold maximum force. This ensures that the force which the vibration member 6 applies to the foil 3, during vibration, can be maintained within a predefined range which is between the threshold minimum force and threshold maximum force.

The controller 120 is further configured to operate the positioning unit 18 to move the vibration unit 5 in a direction which is towards the foil 3, prior to the vibration unit 5 being operated to vibrate the vibration member 6. Specifically, the controller 120 is configured to operate the positioning unit 18 to move the vibration unit 5 in a direction which is towards the foil 3, until the vibration member 5 applies a predefined initial force to the foil 3. In other words, the controller 120 is configured to operate the positioning unit 18 to move the vibration unit 5 in a direction which is towards the foil 3, prior to the vibration unit 5 being operated to vibrate the vibration member 6, until the measurement the controller 120 receives from the force sensor 11 reaches said predefined initial force. Preferably the predefined initial force is in the range 0.1N-0.3N; most preferably the predefined initial force is 0.15N. The controller 120 may be operably connected to the vibration unit 5; and the controller 120 may be configured to initiate the vibration unit 5 to vibrate the vibration member 6, when the vibration member 6 applies the predefined initial force to the foil 3. However, it is not essential the controller 120 be operably connected to the vibration unit 5; it is not essential that the controller 120 be configured to initiate the vibration unit 5 to vibrate the vibration member 6. It should be understood that in the present invention the predefined initial force could be a predefined force range or could be a specific force value.

In an embodiment the controller 120 is configured to operate the positioning unit 18 to move the vibration unit 5 in a direction which is towards the foil 3, prior to operating the vibration unit 5 to vibrate the vibration member 6, so as to move the free end 7a of the vibration member 6, into contact with the second surface 3b of the foil 3; and then move the free end 7a of the vibration member 6 a further predefined distance in the direction towards the foil 3 after contact. Most preferably the predefined distance is in the range 0.1 mm-0.5 mm. Typically moving the move the free end 7a of the vibration member 6 a further 0.1 mm-0.5 mm distance in the direction towards the foil 3 after the free end 7a has initially contacted the foil 3, ensures that the vibration member 6 applies a desired initial force to the foil 3 prior to operating the vibration unit 5 to vibrate the vibration member 6. The controller 120 may be operably connected to the vibration unit 5; and the controller 120 may be configured to initiate the vibration unit 5 to vibrate the vibration member 6, after the free end 7a of the vibration member 6 has been moved said further predefined distance in the direction of the foil 3 after contact. However, it is not essential the controller 12 be operably connected to the vibration unit 5; it is not essential that the controller 120 be configured to initiate the vibration unit 5 to vibrate the vibration member 6.

The vibration member 6 generates vibrations in the foil 3 which loosen the die 2a from the first surface 3a of the foil 3. Preferably the assembly 103 further comprises a pickup head which is operable to pick the loosened die from the foil 3; the pickup head preferably holds the loosened die 2a by means of a vacuum. The pickup head may be provided on a rotatable turret; the rotatable turret preferably comprises a plurality of pickup heads; preferably when a pickup head on the turret has picked a loosened die 2a from the foil, that pickup head will hold said die 2a by means of a vacuum; the turret will then rotate to move the next pickup head on the turret into a position where it can pick the next die loosened from the foil 3.

According to a further aspect of the present invention there is provided a method of removing a die 2a from a foil 3. The assembly 103 can be used to perform the method of the present invention.

The method of removing a die 2a from a foil 3, comprises steps,
(a) providing a foil 3 which has a first surface 3a and a second, opposite, surface 3b, wherein the foil 3 has one or more die 2 attached to the first surface 3a;
(b) aligning a vibration member 6 with a die 2a which is to be removed from the foil 3;
(c) while maintaining said alignment moving the vibration member 6 to bring it into contact with the second surface 3b of the foil 3;
(d) measuring the force that the vibration member 6 is applying to the foil 3;
(e) continuing to move the vibration member 6 in a direction towards the foil 3 until the vibration member 6 applies a force (i.e. an initial force) to the foil 3 which is within a predefined initial force range;
(f) vibrating the vibration member 6, to generate vibrations in the foil 3 which loosen the die 2a from the first surface 3a of the foil 3;
(g) picking the loosened die 2a from the first surface 3a of the foil 3.

In a preferred embodiment the step (f) of vibrating the vibration member 6 comprises vibrating the vibration member 6 at a frequency between 80 kHz-110 kHz. Preferably the vibration member 6 vibrates with a constant amplitude of vibration between 2 μm-10 μm.

In a preferred embodiment, the predefined initial force range in the range 0.1N-0.3N; most preferably the predefined initial force range is 0.15N.

In a preferred embodiment, step (e) comprises continue moving the vibration member 6 a further distance between 0.1 mm-0.5 mm, in the direction towards the foil 3, after vibration member 6 comes into contact with the foil. Typically, moving the vibration member 6 a further 0.1 mm-0.5 mm, in the direction towards the foil 3, ensures that the vibration member 6 applies a desired initial force to the foil 3 prior to operating the vibration unit 5 to vibrate the vibration member 6. The movement of the vibration unit 5 may be done by the positioning unit 18 which is operated by the controller 12; and the force which the vibration member 6 is applying to the foil 3 can be measured using the force sensor 11.

In a preferred embodiment the method further comprises measuring the force that the vibration member 6 is applying to the foil 3 when the vibration member 6 is vibrating, and moving the vibration member 6 in a direction which is towards the foil 3 if the measured force falls below a threshold minimum force; and moving the vibration member 6 in a direction which is away from the foil 3 if the measured force exceeds a threshold maximum force. It should be understood that in the assembly 103, because the vibration member 6 is attached to the vibration unit 5, moving the vibration member 6 away from the foil 3 can be achieved by moving the vibration unit 5 away from the foil 3; likewise, moving the vibration member 6 towards the foil 3 can be achieved by moving the vibration unit 5 towards the foil 3. The movement of the vibration unit 5 may be done by the positioning unit 18 which is operated by the controller 12. Also in the assembly 103 the force that the vibration member 6 is applying to the foil 3 when the vibration member 6 is vibrating can be measured using the force sensor 11.

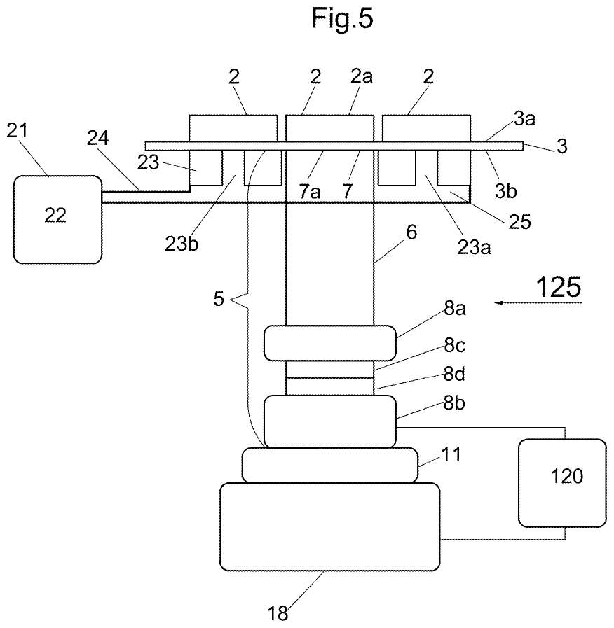

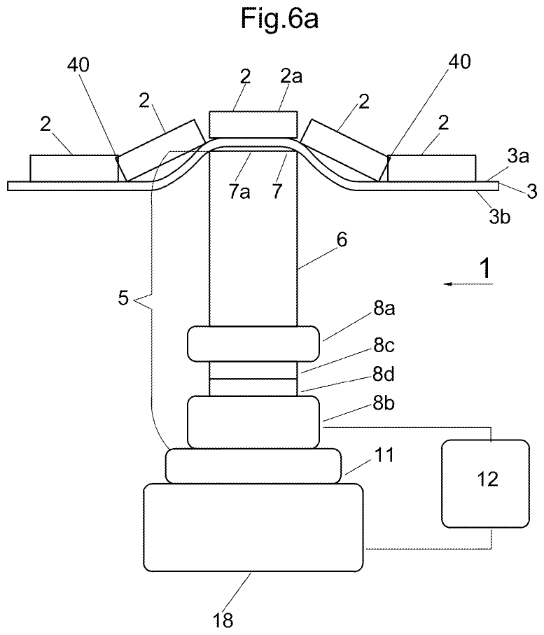

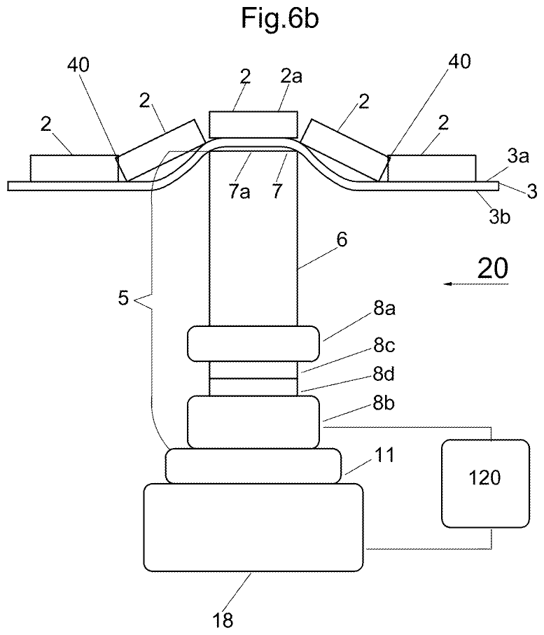

In an embodiment the method further comprises the step of, identifying if two or more die 2 on the foil 3 come into contact when continuing to move the vibration member 6 in a direction towards the foil 3. In other words, when carrying out step (e) identifying if two or more die 2 on the first surface 3a of the foil 3 come into contact. As illustrated in FIGS. 6a and 6b, when continuing to move the vibration member 6 in a direction towards the foil 3, if the foil 3 is too slack, then the vibration 6 will push a portion of the foil 3 upwards to create such curvature in a portion of foil 3 that adjacent die 2 will contact 40 one another (although FIGS. 6a and 6b illustrate assemblies 1 and 20, it should be understood that the very same problem of adjacent die 2 contacting can occur in all assemblies of the present invention, including assemblies 103, 125 of FIGS. 4 and 5 respectively). Identifying, if two or more die 2 on the foil 3 come into contact can be done using any suitable means, such as using a camera which captures images/video of the die 2 on the foil.

In one embodiment, if it is identified that two or more die 2 on the foil 3 come into contact when continuing to move the vibration member 6 in a direction towards the foil 3, before the vibration member 3 is moved far enough in the direction towards the foil 3 to apply a force to the foil 3 which is within the predefined initial force range, then the method further comprises, moving the vibration member 6 away from the foil 3 (preferably moving the vibration member 6 away from the foil 3 so that the vibration member 6 no longer contacts the foil 3); and then transferring all of (or at least some of) die 2 that are on the foil 3 to another, stiffer, foil. After the die 2 have been transferred to the stiffer foil, the method steps (a)-(g) of the present invention are then carried out to remove the die from the surface of the stiffer foil. Any of the assemblies of the present invention may further comprise a plurality of foils having different stiffnesses; accordingly if a foil 3 is too slack so that two or more die 2 on the foil 3 come into contact when continuing to move the vibration member 6 in a direction towards the foil 3, before the vibration member 3 is moved far enough in the direction towards the foil 3 to apply a force to the foil 3 which is within the predefined initial force range, then a user can select from the plurality of foils a foil having greater stiffness; the die 2 which are on the foil 3 can then be transferred to the selected stiffer foil before carrying out method steps (a)-(g) to remove the die 2a from the stiffer foil.

In the method of the present invention the vibration member 6, to generate vibrations in the foil 3 which loosen the die 2a from the first surface 3a of the foil 3. Preferably the loosened die 2a is picked from the foil by a pickup head; the pickup head holds the loosened die 2a by means of a vacuum. The pickup head may be provided on a rotatable turret; the rotatable turret preferably comprises a plurality of pickup head; preferably when a pickup head on the turret has picked a loosened die 2a from the foil, that pickup head will hold said die 2a by means of a vacuum; the turret will then rotate to move the next pickup head on the turret into a position where it can pick the next die loosened from the foil.

FIG. 5 provides a front view of an assembly 125 according to an embodiment of the present invention, which can be used to remove a die 2a from a foil 3. The assembly 125 has all the features of the assembly 120 in FIG. 4 and like features are awarded the same reference numbers.

The assembly 125 further comprises a vacuum generator unit 21. The vacuum generator unit 21 comprises a vacuum generating means 22 and a plate member 23 having a plurality of through-holes 23a defined therein; each of said through-holes 23a,23b being fluidly connected to the vacuum generating means 22 via a conduit 24 and vacuum chamber 25.

Importantly in the assembly 125, the plate member 23 has at least a first through-hole 23a and a second through-hole 23b; and the plate member 23 is moved into contact with the second surface 3b of the foil 3 and arranged so that when the vibration member 6 is aligned beneath a die 2a which is to be removed from the foil 3, the first and second through-holes 23a,23b are located on opposite sides of the vibration member 6. The position of the first and second through-holes 23a,23b is such that when the vibration member 6 is aligned beneath a die 2a which is to be removed from the foil 3, the first through-hole 23a will be aligned beneath an adjacent die 2 which is on side of the die 2a which is to be removed, and the second through-hole 23b will be aligned beneath an adjacent die 2 which is on the other side of the die 2a which is to be removed. In other words position of the first and second through-holes 23a,23b is such that when the vibration member 6 is aligned beneath a die 2a which is to be removed from the foil 3, the first and second through-holes 23a,23b will be aligned beneath respective dies 2 which are adjacent to said die 2a which is to be removed. During use, at least when steps (e) and/or (f) and/or (g) using the vacuum generator unit 21 a vacuum is applied to the second surface 3b of the foil 3; the vacuum will serve to maintain the parts of the foil 3 on which the adjacent dies 2 are mounted, flat, when steps (e) and/or (f) and/or (g) are being carried out, so as to prevent the adjacent dies 2 which are mounted on the foil from becoming displaced from the foil 3 when steps (e) and/or (f) and/or (g) are being carried out to remove the die 2a from the foil 3. Specifically by applying a vacuum to the second surface of the foil when steps (e) and/or (f) and/or (g) are being performed, the vacuum will the amount of curvature in the parts of the foil 3 on which the adjacent dies 2 are mounted-curvature in the foil 3 will thus be localized to the part of the foil 3 on which the die 2a which is to be removed is located—as a result the adjacent dies 2 can maintain the majority of their respective surfaces in contact with the first surface 3a of the foil, and thereby maintain a stable adhesion to the first surface 3a of the foil, which in turn reduces the risk that these adjacent dies 2 become displaced when steps (e) and/or (f) and/or (g) are performed to remove the die 2a.

Accordingly in a further embodiment of the method of removing a die from a foil, there is further a step of applying a vacuum to the second surface 3b of the foil, at least when steps (e) and/or (f) and/or (g) are being carried out. In the most preferred embodiment the vacuum is applied to the second surface 3b of the foil 3, at the parts of the second surface 3b which are aligned with the die 2 which are adjacent to the die 2a which is to be removed. It should be understood that in some cases there will be only one single die adjacent to the die 2a which is to be removed; for example if the die 2a which is to be removed in at an edge of the wafer it can be that there is only one single die adjacent to it; accordingly it should be understood that in this embodiment a vacuum may only need to be applied to one single adject die. In a further variation the plate member 23 may have a plurality of through-holes e.g. four through holes, allowing a vacuum to be applied to a plurality of dies which are surrounding or near to the die 2a which is to be picked. For example, if the die to be picked has four adjacent dies then a vacuum may be applied to the second surface 3b of the foil 3 so that the parts of the foil 3 on which these four adjacent dies 2 are mounted, are maintained flat (or substantially flat), when steps (e) and/or (f) and/or (g) are being carried out. In another example a vacuum may be applied to the second surface 3b of the foil 3 so that so that parts of the foil on which these dies are mounted, are maintained flat (or substantially flat), when steps (e) and/or (f) and/or (g) are being carried out (more generally a vacuum may be applied to the second surface 3b of the foil 3 so that parts of the foil on which any number of dies are mounted, are maintained flat (or substantially flat), when steps (e) and/or (f) and/or (g)). Preferably the number of through-holes in the plate member 23 will correspond to the number of parts of the foil which are to be maintained flat (or substantially flat) when steps (e) and/or (f) and/or (g)), which is equal to the number of dies on the foil that are to be protected from becoming displaced when steps (e) and/or (f) and/or (g)), are being performed. In a further embodiment the plate member 23 may have one or more shutters which can selectively be moved to close a through-hole so that no vacuum can pass through the through hole.

Various modifications and variations to the described embodiments of the invention will be apparent to those skilled in the art without departing from the scope of the invention as defined in the appended claims. Although the invention has been described in connection with specific preferred embodiments, it should be understood that the invention as claimed should not be unduly limited to such specific embodiment.

1. (canceled)

2. (canceled)

3. (canceled)

4. (canceled)

5. (canceled)

6. (canceled)

7. (canceled)

8. (canceled)

9. (canceled)

10. (canceled)

11. (canceled)

12. (canceled)

13. (canceled)

14. An assembly comprising:
a vibration unit comprising a vibration member and operable to vibrate the vibration member at a predefined frequency, wherein the vibration member has a free end with a surface configured to contact a foil having one or more dies attached thereto;
a positioning unit operable to move the vibration unit with respect to the foil; and
a controller configured to operate the positioning unit so that the positioning unit moves the vibration unit to a position in which the vibration member is aligned with a die to be removed from the foil, and so that, while maintaining said alignment, the positioning unit moves the vibration unit to bring the vibration member into contact with a second surface of the foil, and so that the positioning unit moves the vibration unit so that the vibration member is moved, from a start position, a predefined distance in a direction towards the foil,
wherein the controller is further operably connected to the vibration unit and is configured to initiate the vibration unit to vibrate the vibration member to generate vibrations in the foil to loosen the die from a first surface of the foil, after the vibration member has been moved from the start position, the predefined distance in the direction towards the foil.

15. The assembly according to claim 14, further comprising a camera which is configured to capture images of the one or more dies on the foil, and wherein the controller is further configured to carry out processing of said images to determine the distance between adjacent dies of the one or more dies on the foil.

16. The assembly according to claim 15, wherein the one or more dies comprises a plurality of dies, and the controller is further configured to operate the positioning unit to:
move the vibration unit towards the foil so as to move the vibration member towards the foil, until the distance between a least two adjacent ones of the plurality of dies on the foil is zero; and then move the vibration unit in a direction away from the foil until there is at least a distance in a range from 2 μm to 5 μm between all die on the foil, wherein when there is a distance in a range from 2 μm to 5 μm between said two die the vibration member is at an end position; and
wherein the controller further comprises a processor configured to determine said predefined distance as being the difference between said start position and the end position.

17. The assembly according to claim 14, further comprising a force sensor which is operably connected to the vibration unit so that the force sensor senses the force which the vibration member applies to the foil; wherein the controller is further operably connected to the force sensor and is configured to operate the positioning unit to move the vibration unit in a direction which is towards the foil if the measurement of the force sensor falls below a threshold minimum force, until the vibration member applies a force to the foil which is above said threshold minimum force; and to operate the positioning unit to move the vibration unit in a direction which is away from the foil if the measurement of the force sensor exceeds a threshold maximum force, until the vibration member applies a force to the foil which is below said threshold maximum force.

18. The assembly according to claim 14, wherein the predefined distance is in a range from 0.1 mm to 0.5 mm.

19. The assembly according to claim 14, wherein the vibration unit is configured to vibrate the vibration member at a frequency between 80 kHz-110 KHz.

20. The assembly according to claim 14, wherein the vibration unit is configured to vibrate the vibration member with a constant amplitude of vibration between 2 μm to 10 μm.

21. The assembly according to claim 14, wherein the vibration unit comprises an ultrasonic transducer and the vibration member comprises a sonotrode.

22. The assembly according to claim 14, further comprising a vacuum generator unit which is operable to apply a vacuum to the second surface of the foil.

23. The assembly according to claim 14, further comprising a pickup head which is operable to pick a die which has been loosened from the foil by the vibrations of the vibration member.

24. The assembly according to claim 14, wherein the surface of the free end of the vibration member is flat or has a plurality of ridges.

25. The assembly according to claim 14, wherein the surface of the free end of the vibration member has a shape and a dimension that are equal to a shape and a dimension of a surface of the die to be removed from the foil.

26. The assembly according to claim 14, wherein the surface of the free end of the vibration member, has a square area in a range from 2 mm*2 mm to 12 mm*12 mm, or a square area in a range from 0.2 mm*0.2 mm to 1 mm*1 mm.

27. The assembly according to claim 14, wherein the vibration member is removably attached to the vibration unit, and wherein the assembly further comprises a plurality of different vibration members, having different sized surfaces at their respective free ends and/or having different surface profiles at their respective free ends, wherein each of the plurality of different vibration members is removably attached to the vibration unit.

28. (canceled)

29. (canceled)

30. (canceled)

31. (canceled)

32. (canceled)

33. (canceled)

34. (canceled)

35. (canceled)

36. (canceled)

37. An assembly comprising:
a vibration unit comprising a vibration member and is operable to vibrate the vibration member at a predefined frequency, wherein the vibration member has a free end with a surface configured to contact a foil having one or more dies attached thereto;
a force sensor which is operably connected to the vibration unit so that the force sensor is configured to sense the force which the vibration member applies to the foil; and
a controller which is operably connected to the force sensor so that the controller is configured to receive a measurement of the force which the vibration member applies to the foil, and wherein the controller is further operably connected to a positioning unit which is selectively operable to move the vibration unit in a direction which is towards the foil or in a direction which is away from the foil,
wherein the controller is configured to operate the positioning unit to move the vibration unit in the direction towards the foil, prior to the vibration unit being operated to vibrate the vibration member, until the vibration member applies a force to the foil which is within a predefined initial force range.

38. The assembly according to claim 37, wherein the controller is further configured to operate the positioning unit to move the vibration unit in the direction which is towards the foil if the measurement of the force sensor falls below a threshold minimum force; and to operate the positioning unit to move the vibration unit in the direction which is away from the foil if the measurement of the force sensor exceeds a threshold maximum force.

39. The assembly according to claim 37, wherein the controller is configured to operate the positioning unit to move the vibration unit in the direction which is towards the foil, prior to operating the vibration unit to vibrate the vibration member, so as to move the free end of the vibration member into contact with the foil, and then move the free end of the vibration member a further predefined distance in the direction of the foil after contact.

40. (canceled)

41. (canceled)

42. (canceled)

43. (canceled)

44. The assembly according to claim 37, further comprising a vacuum generator unit operable to apply a vacuum to one more dies adjacent to a die being removed from the foil.

45. The assembly according to claim 37, further comprising a pickup head which is operable to pick a die which has been loosened from the foil by the vibrations of the vibration member.

46. (canceled)

47. (canceled)

48. (canceled)

49. (canceled)

50. The assembly according to claim 37, wherein the vibration member is removably attached to the vibration unit, and wherein the assembly further comprises a plurality of different vibration members, having different sized surfaces at their respective free ends and/or having different surface profiles at their respective free ends, wherein each of the plurality of different vibration members is removably attached to the vibration unit.
